(19) United States
(12) Patent Application Publication
(10) Pub. No.: US 2014/0152375 A1
(43) Pub. Date: Jun. 5, 2014

(54) MULTIPLEXER AND DYNAMIC BIAS SWITCH THEREOF

(71) Applicant: HIMAX TECHNOLOGIES LIMITED, Tainan City (TW)

(72) Inventor: Wei-Kai Tseng, Tainan City (TW)

(73) Assignee: HIMAX TECHNOLOGIES LIMITED, Tainan City (TW)

(21) Appl. No.: 13/705,104

(22) Filed: Dec. 4, 2012

(51) Int. Cl. H03K 17/56

(52) U.S. Cl. CPC H03K 17/56
USPC 327/407; 327/419

(57) ABSTRACT

A multiplexer and a dynamic bias switch thereof are provided. The dynamic bias switch includes a switch transistor and a dynamic bulk bias (DBB) unit. A first terminal and a second terminal of the switch transistor are respectively coupled to a first terminal and a second terminal of the dynamic bias switch. A bulk of the switch transistor is coupled to the DBB unit. The DBB unit selectively couples the first terminal or the second terminal of the switch transistor to the bulk of the switch transistor.

### BACKGROUND OF THE INVENTION

1. Field of the Invention

The invention generally relates to a multiplexer, and more particularly, to a dynamic bias switch in a multiplexer.

2. Description of Related Art

When a P-channel metal oxide semiconductor (PMOS) transistor is used, the bulk of the PMOS transistor is usually connected to the highest voltage level (for example, a system voltage VDD) of the system in order to prevent the junction between the source (or the drain) and the bulk from being enabled. While when a N-channel metal oxide semiconductor (NMOS) transistor is used, the bulk of the NMOS transistor is usually connected to the lowest voltage level (for example, the ground voltage) of the system in order to present the junction between the source (or the drain) and the bulk from being enabled. However, when such a conventional technique is applied to a switch or a multiplexer (or mux), a body effect may be produced due to the voltage difference between the source and the bulk of the transistor. The body effect causes the threshold voltage of the metal oxide semiconductor (MOS) transistor to increase. If such a switch or multiplexer is disposed on an output mux of a source driver, the driving performance of the operational amplifier (OP-AMP) may be affected.

### SUMMARY OF THE INVENTION

Accordingly, the invention is directed to a multiplexer and a dynamic bias switch thereof, in which the bulk bias of the multiplexer is dynamically changed to avoid the body effect.

According to an embodiment of the invention, a multiplexer including a first switch, a second switch, a third switch and a fourth switch is provided. A first terminal and a second terminal of the first switch are respectively coupled to a first port and a second port of the multiplexer. A first terminal and a second terminal of the second switch are respectively coupled to a third port and the second port of the multiplexer. A first terminal and a second terminal of the third switch are respectively coupled to the first port and a fourth port of the multiplexer. A first terminal and a second terminal of the fourth switch are respectively coupled to the third port and the fourth port of the multiplexer. At least one of the first switch, the second switch, the third switch and the fourth switch is a dynamic bias switch. The dynamic bias switch includes a first switch transistor and a dynamic bulk bias (DBB) unit. A first terminal and a second terminal of the first switch transistor are respectively coupled to a first terminal and a second terminal of the dynamic bias switch. A bulk of the first switch transistor is coupled to the DBB unit. The DBB unit selectively couples the first terminal or the second terminal of the first switch transistor to the bulk of the first switch transistor.

According to an embodiment of the invention, a dynamic bias switch including a first switch transistor and a DBB unit is provided. A first terminal and a second terminal of the first switch transistor are respectively coupled to a first terminal and a second terminal of the dynamic bias switch. The DBB unit is coupled to a bulk of the first switch transistor. The DBB unit selectively couples the first terminal or the second terminal of the first switch transistor to the bulk of the first switch transistor.

As described above, in an embodiment of the invention, a DBB unit can dynamically couple a first terminal or a second terminal of a first switch transistor to a bulk of the first switch transistor, so that the voltage difference between the source and the bulk of the first switch transistor can be reduced and accordingly the body effect can be avoided.

These and other exemplary embodiments, features, aspects, and advantages of the invention will be described and become more apparent from the detailed description of exemplary embodiments when read in conjunction with accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit diagram of a multiplexer according to an embodiment of the invention.

FIG. 2 is a circuit diagram of a dynamic bias switch according to an embodiment of the invention.

FIG. 3 is a circuit diagram of a dynamic bias switch according to another embodiment of the invention.

FIG. 4 is a circuit diagram of a dynamic bias switch according to yet another embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

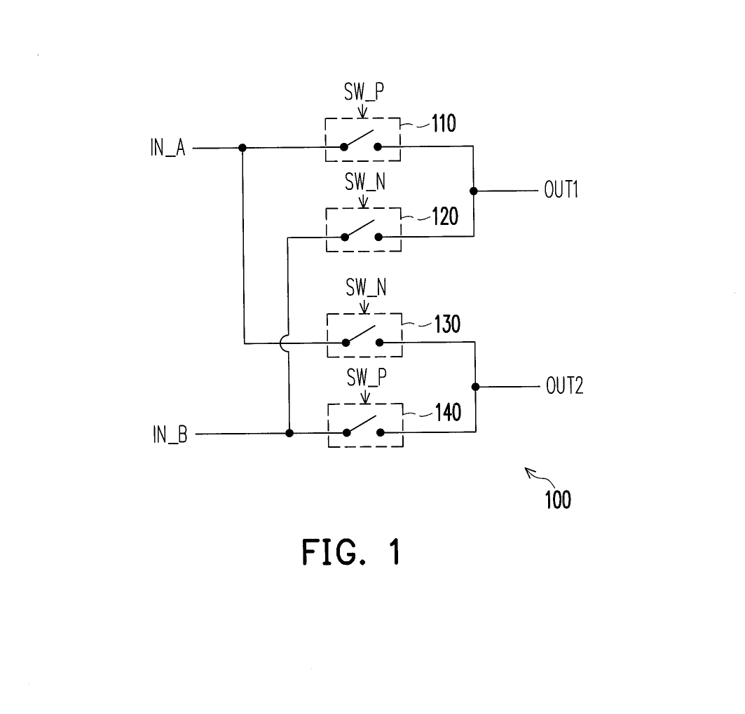

FIG. 1 is a circuit diagram of a multiplexer 100 according to an embodiment of the invention. The multiplexer 100 includes a first switch 110, a second switch 120, a third switch 130 and a fourth switch 140. A first terminal and a second terminal of the first switch 110 are respectively coupled to a first port IN_A and a second port OUT1 of the multiplexer 100. A first terminal and a second terminal of the second switch 120 are respectively coupled to a third port IN_B and the second port OUT1 of the multiplexer 100. A first terminal and a second terminal of the third switch 130 are respectively coupled to the first port IN_A and a fourth port OUT2 of the multiplexer 100. A first terminal and a second terminal of the fourth switch 140 are respectively coupled to the third port IN_B and the fourth port OUT2 of the multiplexer 100.

The first switch 110 and the fourth switch 140 are controlled by a control signal SW_P, and the second switch 120 and the third switch 130 are controlled by a control signal SW_N. When the first switch 110 is turned on, the second switch 120 and the third switch 130 are turned off and the fourth switch 140 is turned on. When the first switch 110 is turned off, the second switch 120 and the third switch 130 are turned on and the fourth switch 140 is turned off. At least one of the first switch 110, the second switch 120, the third switch 130 and the fourth switch 140 is a dynamic bias switch. Below, the implementation of the dynamic bias switch will be explained with reference to several embodiments.

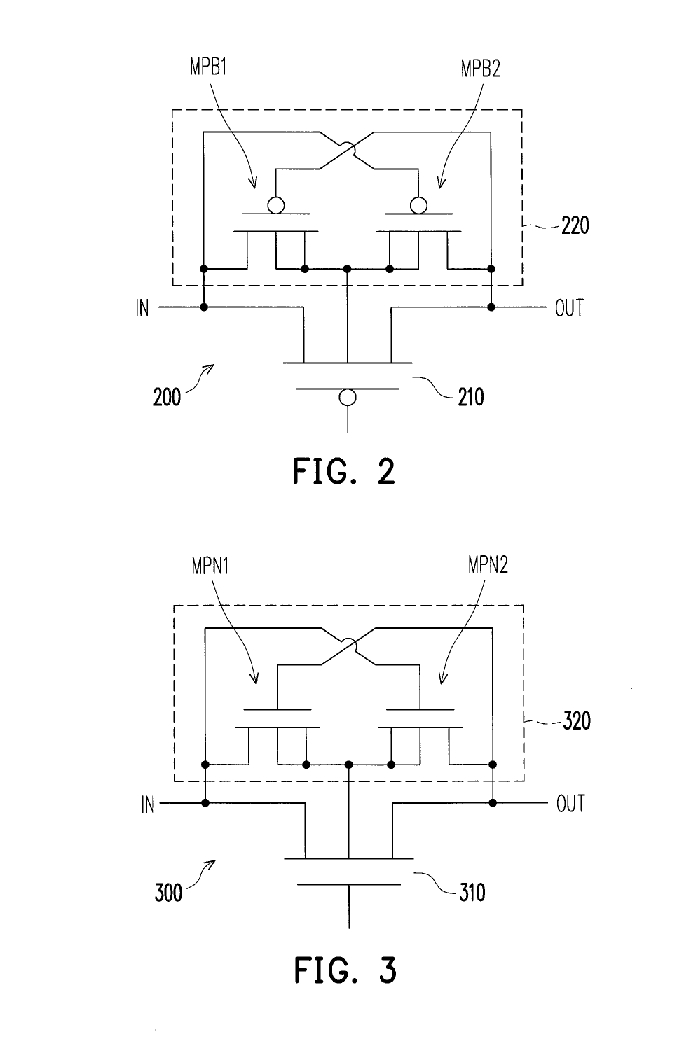

FIG. 2 is a circuit diagram of a dynamic bias switch 200 according to an embodiment of the invention. The dynamic bias switch 200 includes a switch transistor 210 and a dynamic bulk bias (DBB) unit 220. In the present embodiment, the switch transistor 210 may be a P-channel metal oxide semiconductor (PMOS) transistor. A first terminal and a second terminal of the switch transistor 210 are respectively coupled to a first terminal IN and a second terminal OUT of the dynamic bias switch 200. Any one of the first switch 110, the second switch 120, the third switch 130 and the fourth switch 140 in FIG. 1 can be implemented by referring to related descriptions of FIG. 2. For example, if the first switch 110 in FIG. 1 is realized with the dynamic bias switch 200 in FIG. 2, the first terminal IN and the second terminal OUT of the dynamic bias switch 200 are respectively coupled to the first port IN_A and the second port OUT1 of the multiplexer 100, and a control terminal (for example, the gate) of the switch transistor 210 receives the control signal SW_P. The other switches 120-140 in FIG. 1 can be implemented by referring to related descriptions of the first switch 110.

A bulk of the switch transistor 210 is coupled to the DBB unit 220. The DBB unit 220 selectively couples the first terminal or the second terminal of the switch transistor 210 to the bulk of the first switch transistor 210. By reducing the voltage difference between the source and the bulk of the switch transistor 210, the body effect can be avoided.

However, due to the symmetry requirement in structure/appearance or some application requirements, a metal oxide semiconductor (MOS) transistor has no implicit source/drain. The source and drain of a MOS transistor are defined according to the flow direction of “most carriers”. For example, because most carriers in a PMOS transistor are electron holes, the end for “current” to enter the PMOS transistor is referred to as the source, while the end for “current” to exit the PMOS transistor is referred to as the drain. Because most carriers in a N-channel metal oxide semiconductor (NMOS) transistor are electrons, the end for “electron current” to enter the NMOS transistor is referred to as the source, while the end for “electron current” to exit the NMOS transistor is referred to as the drain.

Thereby, if the voltage on the first terminal of the switch transistor 210 (i.e., the first terminal IN of the dynamic bias switch 200) is higher than the voltage on the second terminal of the switch transistor 210 (i.e., the second terminal OUT of the dynamic bias switch 200), the first terminal of the switch transistor 210 can be considered as the source, while the second terminal of the switch transistor 210 can be considered as the drain. Contrarily, if the voltage on the first terminal of the switch transistor 210 is lower than the voltage on the second terminal thereof, the first terminal of the switch transistor 210 can be considered as the drain, while the second terminal of the switch transistor 210 can be considered as the source. In order to prevent the P/N junction between the source (or the drain) and the bulk from being enabled and to avoid the body effect, the DBB unit 220 allows the bulk of the switch transistor 210 to be automatically/dynamically biased to an appropriate voltage level.

In order to prevent the PN junction between the source (or the drain) and the bulk of the switch transistor 210 from being enabled, the DBB unit 220 should control the voltage on the bulk of the switch transistor 210 to be equal to or higher than the voltage on the source of the switch transistor 210. In order to avoid the body effect, the DBB unit 220 should control the voltage on the bulk of the switch transistor 210 to be equal to the voltage on the source of the switch transistor 210. Accordingly, the DBB unit 220 should allow the bulk of the switch transistor 210 to be automatically/dynamically coupled to one of the first terminal and the second terminal of the switch transistor 210 that has a higher voltage level.

The implementation of the DBB unit 220 is not limited in the present embodiment. Any circuit that can dynamically couple the first terminal or the second terminal of the switch transistor 210 (whichever has a higher voltage level) to the bulk of the switch transistor 210 can be adopted for implementing the DBB unit 220. FIG. 2 illustrates an implementation example of the DBB unit 220. The DBB unit 220 includes a first bias transistor MPB1 and a second bias transistor MPB2. A first terminal of the first bias transistor MPB1 is coupled to the first terminal of the switch transistor 210 (i.e., the first terminal IN of the dynamic bias switch 200). A second terminal of the first bias transistor MPB1 is coupled to the bulk of the switch transistor 210. A control terminal (for example, the gate) of the first bias transistor MPB1 is coupled to the second terminal of the switch transistor 210 (i.e., the second terminal OUT of the dynamic bias switch 200). A first terminal of the second bias transistor MPB2 is coupled to the second terminal of the switch transistor 210. A second terminal of the second bias transistor MPB2 is coupled to the bulk of the switch transistor 210. A control terminal (for example, the gate) of the second bias transistor MPB2 is coupled to the first terminal of the switch transistor 210.

In the present embodiment, bulks of the first bias transistor MPB1 and the second bias transistor MPB2 are both coupled to the bulk of the switch transistor 210. The first bias transistor MPB1, the second bias transistor MPB2 and the switch transistor 210 are all P conduction type (i.e., are all PMOS transistors). Thus, if the voltage on the first terminal of the switch transistor 210 (i.e., the first terminal IN of the dynamic bias switch 200) is higher than the voltage on the second terminal of the switch transistor 210 (i.e., the second terminal OUT of the dynamic bias switch 200), the second bias transistor MPB2 is turned off while the first bias transistor MPB1 is turned on. In this case, the bulk voltages of the three MOS transistors (i.e., the first bias transistor MPB1, the second bias transistor MPB2 and the switch transistor 210) are all set to the voltage on the first terminal of the switch transistor 210 (i.e., the first terminal IN of the dynamic bias switch 200).

FIG. 3 is a circuit diagram of a dynamic bias switch 300 according to another embodiment of the invention. The dynamic bias switch 300 includes a switch transistor 310 and a DBB unit 320. In the present embodiment, the switch transistor 310 may be a NMOS transistor. A first terminal and a second terminal of the switch transistor 310 are respectively coupled to a first terminal IN and a second terminal OUT of the dynamic bias switch 300. Any one of the first switch 110, the second switch 120, the third switch 130 and the fourth switch 140 in FIG. 1 can be implemented by referring to related descriptions of FIG. 3. For example, if the first switch 110 in FIG. 1 is realized with the dynamic bias switch 300 in FIG. 3, the first terminal IN and the second terminal OUT of the dynamic bias switch 300 are respectively coupled to the first port IN_A and the second port OUT1 of the multiplexer 100, a control terminal (for example, the gate) of the switch transistor 310 receives the control signal SW_P. The other switches 120-140 in FIG. 1 can be implemented by referring to related descriptions of the first switch 110.

A bulk of the switch transistor 310 is coupled to the DBB unit 320. The DBB unit 320 selectively couples the first terminal or the second terminal of the switch transistor 310 to the bulk of the switch transistor 310. By reducing the voltage difference between the source and the bulk of the switch transistor 310, the body effect can be avoided. Thus, if the voltage on the first terminal of the switch transistor 310 (i.e., the first terminal IN of the dynamic bias switch 300) is higher than the voltage on the second terminal of the switch transistor 310 (i.e., the second terminal OUT of the dynamic bias switch 300), the first terminal of the switch transistor 310 can be considered as the drain, and the second terminal of the switch transistor 310 can be considered as the source. Contrarily, if the voltage on the first terminal of the switch transistor 310 is lower than the voltage on the second terminal of the switch transistor 310, the first terminal of the switch transistor 310 can be considered as the source, and the second terminal of the switch transistor 310 can be considered as the drain. In order to prevent the PN junction between the source (or the drain) and the bulk from being enabled and to avoid the body effect, the DBB unit 320 allows the bulk of the switch transistor 310 to be automatically/dynamically coupled to one of the first terminal and the second terminal of the switch transistor 310 that has a lower voltage level.

The implementation of the DBB unit 320 is not limited in the present embodiment. Any circuit that can dynamically couple the first terminal or the second terminal of the switch transistor 310 (whichever has a lower voltage level) to the bulk of the switch transistor 310 can be adopted for implementing the DBB unit 320. FIG. 3 illustrates an implementation example of the DBB unit 320. The DBB unit 320 includes a first bias transistor MPN1 and a second bias transistor MPN2. A first terminal of the first bias transistor MPN1 is coupled to the first terminal of the switch transistor 310 (i.e., the first terminal IN of the dynamic bias switch 300). A second terminal of the first bias transistor MPN1 is coupled to the bulk of the switch transistor 310. A control terminal (for example, the gate) of the first bias transistor MPN1 is coupled to the second terminal of the switch transistor 310 (i.e., the second terminal OUT of the dynamic bias switch 300). A first terminal of the second bias transistor MPN2 is coupled to the second terminal of the switch transistor 310. A second terminal of the second bias transistor MPN2 is coupled to the bulk of the switch transistor 310. A control terminal (for example, the gate) of the second bias transistor MPN2 is coupled to the first terminal of the switch transistor 310.

In the present embodiment, bulks of the first bias transistor MPN1 and the second bias transistor MPN2 are both coupled to the bulk of the switch transistor 310. The first bias transistor MPN1, the second bias transistor MPN2 and the switch transistor 310 are all N conduction type (i.e., are all NMOS transistors). Thus, if the voltage on the first terminal of the switch transistor 310 (i.e., the first terminal IN of the dynamic bias switch 300) is higher than the voltage on the second terminal of the switch transistor 310 (i.e., the second terminal OUT of the dynamic bias switch 300), the first bias transistor MPN1 is turned off and the second bias transistor MPN2 is turned on. In this case, the bulk voltages of the three MOS transistors (i.e., the first bias transistor MPN1, the second bias transistor MPN2 and the switch transistor 310) are all set to the voltage on the second terminal of the switch transistor 310 (i.e., the second terminal OUT of the dynamic bias switch 300).

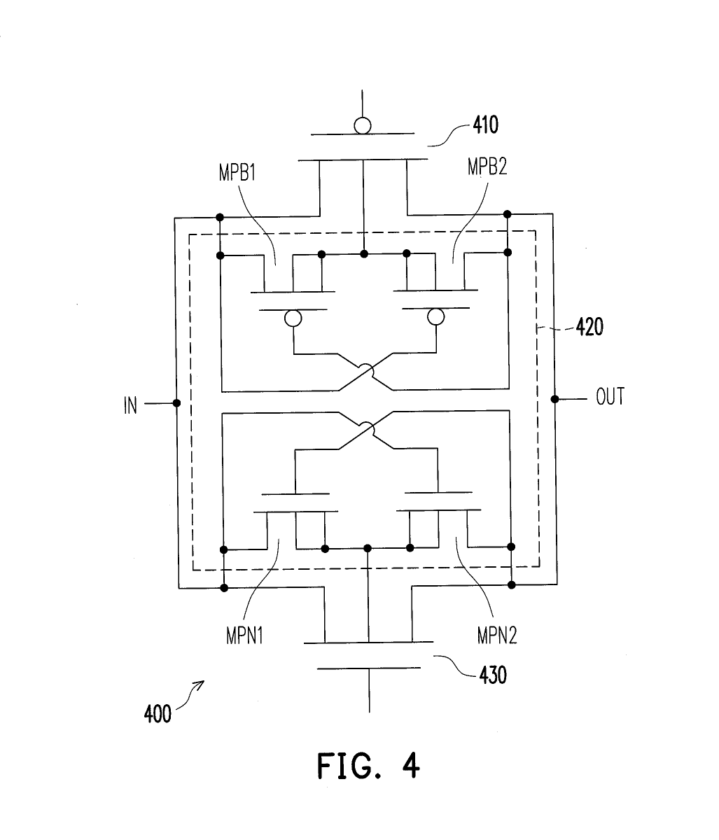

FIG. 4 is a circuit diagram of a dynamic bias switch 400 according to yet another embodiment of the invention. The dynamic bias switch 400 includes a first switch transistor 410, a DBB unit 420 and a second switch transistor 430. In the present embodiment, the first switch transistor 410 may be a PMOS transistor, and the second switch transistor 430 may be a NMOS transistor. A first terminal and a second terminal of the first switch transistor 410 are respectively coupled to a first terminal IN and a second terminal OUT of the dynamic bias switch 400. A first terminal and a second terminal of the second switch transistor 430 are also respectively coupled to the first terminal IN and the second terminal OUT of the dynamic bias switch 400. Any one of the first switch 110, the second switch 120, the third switch 130 and the fourth switch 140 in FIG. 1 can be implemented by referring to related descriptions of FIG. 4. For example, if the first switch 110 in FIG. 1 is realized with the dynamic bias switch 400 in FIG. 4, the first terminal IN and the second terminal OUT of the dynamic bias switch 400 are respectively coupled to the first port IN_A and the second port OUT1 of the multiplexer 100, a control terminal (for example, the gate) of the first switch transistor 410 receives the control signal SW_P, and a control terminal (for example, the gate) of the second switch transistor 430 receives an inverted signal of the control signal SW_P. The other switches 120-140 in FIG. 1 can be implemented by referring to related descriptions of the first switch 110.

Bulks of the switch transistors 410 and 430 are both coupled to the DBB unit 420. The DBB unit 420 selectively couples the first terminal or the second terminal of the first switch transistor 410 to the bulk of the first switch transistor 410 and selectively couples the first terminal or the second terminal of the second switch transistor 430 to the bulk of the second switch transistor 430. By reducing the voltage difference between the source and the bulk of each switch transistor, the body effect can be avoided. Thus, if the voltage on the first terminal IN of the dynamic bias switch 400 is higher than the voltage on the second terminal OUT thereof, the first terminal of the first switch transistor 410 and the second terminal of the second switch transistor 430 can be considered as the sources, and the second terminal of the first switch transistor 410 and the first terminal of the second switch transistor 430 can be considered as the drains. Contrarily, if the voltage on the first terminal IN of the dynamic bias switch 400 is lower than the voltage on the second terminal OUT thereof, the first terminal of the first switch transistor 410 and the second terminal of the second switch transistor 430 can be considered as the drains, and the second terminal of the first switch transistor 410 and the first terminal of the second switch transistor 430 can be considered as the sources. In order to prevent the PN junction between the source (or the drain) and the bulk from being enabled and to avoid the body effect, the DBB unit 420 allows the bulk of the first switch transistor 410 to automatically/dynamically couple to one of the first terminal and the second terminal of the first switch transistor 410 that has a higher voltage level, and allows the bulk of the second switch transistor 430 to automatically/dynamically couple to one of the first terminal and the second terminal of the second switch transistor 430 that has a lower voltage level.

The implementation of the DBB unit 420 is not limited in the present embodiment. FIG. 4 illustrates an implementation example of the DBB unit 420. The DBB unit 420 includes a first bias transistor MPB1, a second bias transistor MPB2, a third bias transistor MPN1 and a fourth bias transistor MPN2. A first terminal of the first bias transistor MPB1 is coupled to the first terminal of the first switch transistor 410 (i.e., the first terminal IN of the dynamic bias switch 400). A second terminal of the first bias transistor MPB1 is coupled to the bulk of the first switch transistor 410. A control terminal of the first bias transistor MPB1 is coupled to the second terminal of the first switch transistor 410 (i.e., the second terminal OUT of the dynamic bias switch 400). A first terminal of the second bias transistor MPB2 is coupled to the second terminal of the first switch transistor 410. A second terminal of the second bias transistor MPB2 is coupled to the bulk of the first switch transistor 410. A control terminal of the second bias transistor MPB2 is coupled to the first terminal of the first switch transistor 410.

A first terminal of the third bias transistor MPN1 is coupled to the first terminal of the second switch transistor 430 (i.e., the first terminal IN of the dynamic bias switch 400). A second terminal of the third bias transistor MPN1 is coupled to the bulk of the second switch transistor 430. A control terminal of the third bias transistor MPN1 is coupled to the second terminal of the second switch transistor 430 (i.e., the second terminal OUT of the dynamic bias switch 400). A first terminal of the fourth bias transistor MPN2 is coupled to the second terminal of the second switch transistor 430. A second terminal of the fourth bias transistor MPN2 is coupled to the bulk of the second switch transistor 430. A control terminal of the fourth bias transistor MPN2 is coupled to the first terminal of the second switch transistor 430.

The bias transistors MPB1, MPB2, MPN1 and MPN2 can be implemented by referring to related descriptions of FIG. 2 and FIG. 3. In the present embodiment, bulks of the bias transistors MPB1 and MPB2 are both coupled to the bulk of the first switch transistor 410, and bulks of the bias transistors MPN1 and MPN2 are both coupled to the bulk of the second switch transistor 430. The first bias transistor MPB1, the second bias transistor MPB2 and the first switch transistor 410 are all P conduction type (i.e., are all PMOS transistors), and the third bias transistor MPN1, the fourth bias transistor MPN2 and the second switch transistor 430 are all N conduction type (i.e., are all NMOS transistors). Thus, if the voltage on the first terminal IN of the dynamic bias switch 400 is higher than the voltage on the second terminal OUT thereof, the transistors MPB2 and MPN1 are turned off and the transistors MPB1 and MPN2 are turned on. In this case, the bulk voltages of the MOS transistors MPB1, MPB2 and the first switch transistor 410 are all set to the voltage on the first terminal of the first switch transistor 410 (i.e., the first terminal IN of the dynamic bias switch 400), and the bulk voltages of the MOS transistors MPN1, MPN2 and the second switch transistor 430 are all set to the voltage on the second terminal of the second switch transistor 430 (i.e., the second terminal OUT of the dynamic bias switch 400).

As described above, in an embodiment of the invention, a DBB unit can dynamically couple a first terminal or a second terminal of a switch transistor to a bulk of the switch transistor, so that the voltage difference between the source and the bulk of the switch transistor can be reduced and accordingly the body effect can be avoided.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A multiplexer, comprising:
a first switch, having a first terminal and a second terminal respectively coupled to a first port and a second port of the multiplexer;
a second switch, having a first terminal and a second terminal respectively coupled to a third port and the second port of the multiplexer;
a third switch, having a first terminal and a second terminal respectively coupled to the first port and a fourth port of the multiplexer; and
a fourth switch, having a first terminal and a second terminal respectively coupled to the third port and the fourth port of the multiplexer;
wherein at least one of the first switch, the second switch, the third switch and the fourth switch is a dynamic bias switch, the dynamic bias switch comprises a first switch transistor and a dynamic bulk bias (DBB) unit, a first terminal and a second terminal of the first switch transistor are respectively coupled to the first terminal and the second terminal of the dynamic bias switch, a bulk of the first switch transistor is coupled to the DBB unit, and the DBB unit selectively couples the first terminal or the second terminal of the first switch transistor to the bulk of the first switch transistor.

2. The multiplexer according to claim 1, wherein the second switch and the third switch are turned off and the fourth switch is turned on when the first switch is turned on; and the second switch and the third switch are turned on and the fourth switch is turned off when the first switch is turned off.

3. The multiplexer according to claim 1, wherein the DBB unit comprises:
a first bias transistor, having a first terminal coupled to the first terminal of the first switch transistor, a second terminal coupled to the bulk of the first switch transistor, and a control terminal coupled to the second terminal of the first switch transistor; and
a second bias transistor, having a first terminal coupled to the second terminal of the first switch transistor, a second terminal coupled to the bulk of the first switch transistor, and a control terminal coupled to the first terminal of the first switch transistor.

4. The multiplexer according to claim 3, wherein bulks of the first bias transistor and the second bias transistor are both coupled to the bulk of the first switch transistor.

5. The multiplexer according to claim 3, wherein conduction types of the first bias transistor, the second bias transistor and the first switch transistor are the same.

6. The multiplexer according to claim 1, wherein the dynamic bias switch further comprises:
a second switch transistor, having a first terminal and a second terminal respectively coupled to the first terminal and the second terminal of the dynamic bias switch, wherein a bulk of the second switch transistor is coupled to the DBB unit, and the DBB unit further selectively couples the first terminal or the second terminal of the second switch transistor to the bulk of the second switch transistor.

7. The multiplexer according to claim 6, wherein the DBB unit comprises:
a first bias transistor, having a first terminal coupled to the first terminal of the first switch transistor, a second terminal coupled to the bulk of the first switch transistor, and a control terminal coupled to the second terminal of the first switch transistor;
a second bias transistor, having a first terminal coupled to the second terminal of the first switch transistor, a second terminal coupled to the bulk of the first switch transistor, and a control terminal coupled to the first terminal of the first switch transistor;
a third bias transistor, having a first terminal coupled to the first terminal of the second switch transistor, a second terminal coupled to the bulk of the second switch transistor, and a control terminal coupled to the second terminal of the second switch transistor; and
a fourth bias transistor, having a first terminal coupled to the second terminal of the second switch transistor, a second terminal coupled to the bulk of the second switch transistor, and a control terminal coupled to the first terminal of the second switch transistor.

8. The multiplexer according to claim 7, wherein bulks of the first bias transistor and the second bias transistor are both coupled to the bulk of the first switch transistor, and bulks of the third bias transistor and the fourth bias transistor are both coupled to the bulk of the second switch transistor.

9. The multiplexer according to claim 7, wherein a conduction type of the first switch transistor is different from a conduction type of the second switch transistor, and conduction types of the first bias transistor, the second bias transistor and the first switch transistor are the same, and conduction types of the third bias transistor, the fourth bias transistor and the second switch transistor are the same.

10. The multiplexer according to claim 1, wherein the DBB unit couples the bulk of the first switch transistor to one of the first terminal and the second terminal of the first switch transistor which has a higher voltage level when the first switch transistor is a P conduction type, and the DBB unit couples the bulk of the first switch transistor to one of the first terminal and the second terminal of the first switch transistor which has a lower voltage level when the first switch transistor is an N conduction type.

11. A dynamic bias switch, comprising:
a first switch transistor, having a first terminal and a second terminal respectively coupled to a first terminal and a second terminal of the dynamic bias switch; and
a DBB unit, coupled to a bulk of the first switch transistor, and selectively coupling the first terminal or the second terminal of the first switch transistor to the bulk of the first switch transistor.

12. The dynamic bias switch according to claim 11, wherein the DBB unit comprises:
a first bias transistor, having a first terminal coupled to the first terminal of the first switch transistor, a second terminal coupled to the bulk of the first switch transistor, and a control terminal coupled to the second terminal of the first switch transistor; and
a second bias transistor, having a first terminal coupled to the second terminal of the first switch transistor, a second terminal coupled to the bulk of the first switch transistor, and a control terminal coupled to the first terminal of the first switch transistor.

13. The dynamic bias switch according to claim 12, wherein bulks of the first bias transistor and the second bias transistor are both coupled to the bulk of the first switch transistor.

14. The dynamic bias switch according to claim 12, wherein conduction types of the first bias transistor, the second bias transistor and the first switch transistor are the same.

15. The dynamic bias switch according to claim 11 further comprising:
a second switch transistor, having a first terminal and a second terminal respectively coupled to the first terminal and the second terminal of the dynamic bias switch, wherein a bulk of the second switch transistor is coupled to the DBB unit, and the DBB unit further selectively couples the first terminal or the second terminal of the second switch transistor to the bulk of the second switch transistor.

16. The dynamic bias switch according to claim 15, wherein the DBB unit comprises:
a first bias transistor, having a first terminal coupled to the first terminal of the first switch transistor, a second terminal coupled to the bulk of the first switch transistor, and a control terminal coupled to the second terminal of the first switch transistor;
a second bias transistor, having a first terminal coupled to the second terminal of the first switch transistor, a second terminal coupled to the bulk of the first switch transistor, and a control terminal coupled to the first terminal of the first switch transistor;
a third bias transistor, having a first terminal coupled to the first terminal of the second switch transistor, a second terminal coupled to the bulk of the second switch transistor, and a control terminal coupled to the second terminal of the second switch transistor; and
a fourth bias transistor, having a first terminal coupled to the second terminal of the second switch transistor, a second terminal coupled to the bulk of the second switch transistor, and a control terminal coupled to the first terminal of the second switch transistor.

17. The dynamic bias switch according to claim 16, wherein bulks of the first bias transistor and the second bias transistor are both coupled to the bulk of the first switch transistor, and bulks of the third bias transistor and the fourth bias transistor are both coupled to the bulk of the second switch transistor.

18. The dynamic bias switch according to claim 16, wherein a conduction type of the first switch transistor is different from a conduction type of the second switch transistor, conduction types of the first bias transistor, the second bias transistor and the first switch transistor are the same, and conduction types of the third bias transistor, the fourth bias transistor and the second switch transistor are the same.

19. The dynamic bias switch according to claim 11, wherein the DBB unit couples the bulk of the first switch transistor to one of the first terminal and the second terminal of the first switch transistor which has a higher voltage level when the first switch transistor is a P conduction type; and the DBB unit couples the bulk of the first switch transistor to one of the first terminal and the second terminal of the first switch transistor which has a lower voltage level when the first switch transistor is an N conduction type.
